(19) United States
(12) Patent Application Publication
(10) Pub. No.: US 2002/0150842 A1
(43) Pub. Date: Oct. 17, 2002

(54) Lithographically patterning of UV cure elastomer thin films

(75) Inventor: Ming Li, Thousand Oaks, CA (US)

Correspondence Address: FLESHNER & KIM, LLP, P.O. Box 221200, Chantilly, VA, 20153-1200, US

(73) Assignee: Solus Micro Technologies, Inc.

(21) Appl. No.: 09/829,974

(22) Filed: Apr. 11, 2001

(51) Int. Cl. G03F 7/00

(52) U.S. Cl. 430/323; 430/327

(57) ABSTRACT

Elastomer thin films can be lithographically patterned by using an UV curable polydimethylsiloxane, rather than replica molding of thermal cure elastomers. The fabrication method of such patterned elastomers consists of elastomer formulation, substrate modification, spinning elastomer, pattern development, and possible a backside etch of the substrate.

### BACKGROUND OF THE INVENTION

1. Field of the Invention

This invention relates to methods of lithographically patterning UV cure silicone elastomer thin films, which have very low Young's modulus and reasonable mechanical strength, to form compliant mechanical structures.

2. Description of the Related Art

Stiff materials such as silicon and glass (Young's modulus of 100 Gpa and 60 Gpa, respectively) are excellent choices for electronic and mechanical micro devices. However, their intrinsic stiffness poses a challenge in making micro devices having moving parts. Moving a silicon valve or template in a micro device requires very high voltage if the micro device is actuated or tuned by an electrostatic force. Alternately, the area of the valve or template can be increased to form a large membrane and the membrane thinned to reduce the required voltage. Such a membrane would be very vulnerable to the environment and would also pose a great fabrication challenge.

Organic polymers such as polydimethylsiloxane (PDMS), a soft material with Young's modulus of ca. 1 Mpa, are receiving an increasing amount of attention. This type of soft material overcomes many of the limitations of aforementioned silicon and glass and offers other advantages. Silicone elastomer is much cheaper than silicon. Elastomers also have a distinctive mechanical property: the Young's modulus can be tuned over two orders of magnitude by controlling the amount of crosslinking between polymer chains or changing the crosslinking mechanisms. Elastomers are forgiving materials to work with, requiring less stringent fabrication conditions than silicon and little capital equipment to set up a fabrication facility. However, since elastomer is an organic polymer. It is difficult to integrate a soft material into the rigors of silicon processing.

The fabrication method for elastomer is currently limited to techniques such as micro molding or stamping. The principle of all of these methods is replica molding. It is a subtractive method since the features of the resulting elastomer stripes are determined by the micromachined mold. Whitesides and co-workers at Harvard University have used such techniques to fabricate various optical components such as blazed grating, waveguide, and three-dimensional conducting coils. Byung-Ho Jo and his coworkers from University of Illinois at Urbana-Champaign cast thin elastomer layers from an embossed master containing channels and openings made of epoxy based photoresist. The elastomer layers were subsequently stacked to form complex 3-D channel devices.

The thermal cured elastomers from GE Silicones or Dow Corning were used in all the aforementioned works. These thermal cure elastomers contain two parts. Part “A” contains a polydimethylsiloxane bearing vinyl groups and a platinum catalyst. Part “B” contains a crosslinker containing silicone hydride groups, which form a covalent bond with vinyl groups. The elastomers are crosslinked or cured as part “A” and “B” are thoroughly mixed and heated. Vinyl and hydride groups can be easily introduced to most of the substrates, including glass, silicon, metals and thermosetting polymer via surface modification. Therefore, elastomers can be cured on and adhere well to these surfaces. However, it is very difficult to adhere a cured elastomer stripe to any surface. Thus, stacking of elastomer stripes cannot adhere well to almost any surfaces. Additionally, it becomes increasingly difficult to mold ultra thin elastomers. Manual handling of thinner elastomer stripes becomes even more difficult since the mechanical strength of the thinner stripes is poorer than that of thicker ones. Also the accuracy of packing micro elastomer strips manually is very inadequate.

Thus, existing elastomer molding and stamping methods have limited applications because they simply do not meet the requirement for volume production of micro devices.

### SUMMARY OF THE INVENTION

In view of the above problems, the present invention provides a simple, robust, and precise method to fabricate patterned elastomer layers in microelectronic and mechanical devices.

This is accomplished by formulation and application of UV curable elastomers, which can be photolithographically patterned. This method does not require any manual handling and packing of elastomer stripes. Further, the feature size on the elastomer is solely determined by the photo masks therefore, thin elastomer layers with micro features can be fabricated easily with this approach. Finally, good adhesion between elastomers and substrates can be easily achieved since the elastomers are cured on the substrate.

These and other features and advantages of the invention will be apparent to those skilled in the art from the following detailed description of preferred embodiments, taken together with the accompanying drawings, in which:

### BRIEF DESCRIPTION OF THE DRAWINGS

FIGS. 1 through 4 illustrate a photolithographic process for patterning UV cure elastomer in accordance with the present invention;

FIG. 5 illustrates an optional backside etch of the substrate to release the patterned elastomer to form a compliant mechanical structure; and

FIGS. 6a through 6d are bond diagrams illustrating the hydrolysis, condensation, hydrogen bonding and covalent bond formation steps associated with the substrate pretreatment.

### DETAILED DESCRIPTION OF THE INVENTION

The present invention provides a simple, robust, and precise method to fabricate patterned elastomer layers in microelectronic and mechanical devices. This is accomplished by formulation and application of UV curable elastomers, which are photolithographically patterned.

### Photolithography and its Chemical Reaction Mechanisms

Photolithography has been particularly important in microelectronic industry. A photolithography process involves coating of a substrate with a polymer that crosslinks under the influence of ultraviolet, visible light or ionizing radiation. A mask carrying the pattern to be transferred to the substrate is placed over the coated surface, and then the surface is irradiated. The pattern allows radiation through, and those portion of the polymer thus exposed undergo crosslinking. When the mask is removed, the unexposed areas of the polymer are dissolved with solvent, leaving behind the desired pattern. The patterned polymer is then used to form microstructures by forming and patterning one or more layers of mechanical or electrical materials over the pattern. When complete, the patterned polymer is “released” and removed from the structure.

The crosslinked polymer becomes resistant to solvent and such a polymer is referred to as a negative resist. Such a photocrosslinking process is achieved by incorporating photosensitizers (photoinitiator) into the polymer, which absorb the light energy and thereby induce formations of free radicals. When triplet sensitizers such as benzophenone are added to the polymer, absorption of ultraviolet results in n→π* excitation of the sensitizer followed by hydrogen abstraction from the polymer to yield the radical sites available for crosslinking by combination reactions. The major advantage of photoinitiation is that the reaction is essentially independent of temperature, thus crosslinking may be conducted at very low temperature. Furthermore, better control of the crosslinking reaction is generally possible because narrow wavelength bands maybe used to initiate the decomposition, and the reaction can be stopped simply by removing the light source.

### Photolithography of UV Cure Elastomer

The invention applies well-known photolithographic techniques to UV cure elastomer materials to form compliant mechanical structures. Unlike conventional photolithography in which the patterned polymer is used a release layer, the patterned elastomer forms an integral part of the particular micro device.

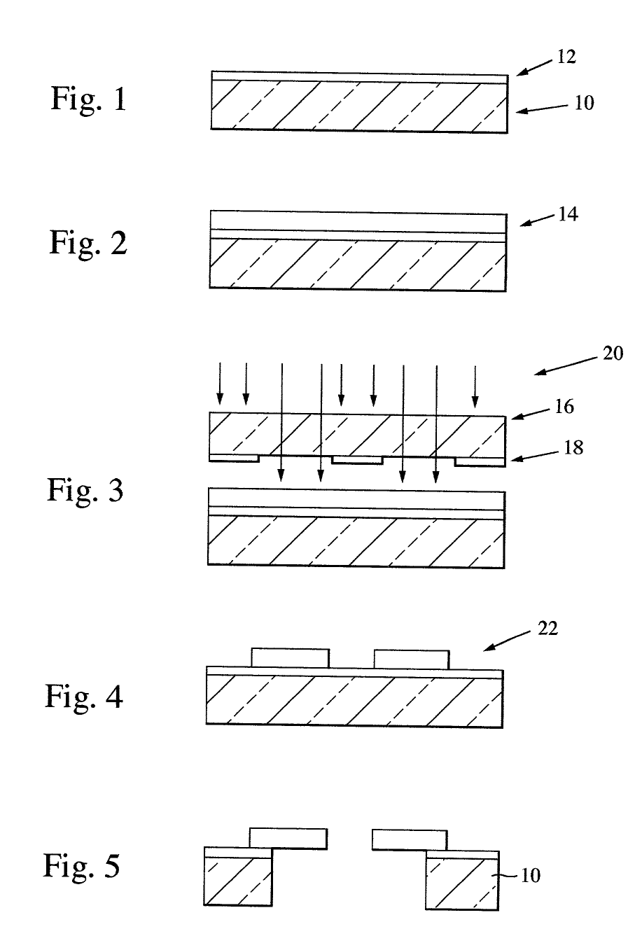

As shown in FIG. 1, the surface of a substrate 10 is treated with adhesion promoter 12. A UV cure elastomer 14 is spun onto the surface modified substrate as shown in FIG. 2. As depicted in FIG. 3a mask 16 carrying the desired pattern 18 to be transferred is placed over the coated surface. The surface is irradiated with UV light 20 through the mask 16. As shown in FIG. 4, the portions of unexposed elastomer are dissolved by solvent, leaving behind the desired pattern.

In many applications, it will be necessary to release the patterned elastomer to forms the compliant mechanical structure 22. As shown in FIG. 5, this is accomplished using a backside etch to remove selected portions of the substrate. For example, if the substrate is silicon, one can apply and pattern a layer of resist on the backside of the substrate, then selectively etch the substrate from backside using KOH or deep RIE, and finally remove the resist.

### Types of UV Curing Systems

There are two types of UV cure elastomer systems included in the present invention. The first type is monofunctional system containing acrylate functional groups such as methacryloxypropyl and/or acryloxypropyl functional polydimethylsiloxane. They undergo rapid UV and visible light polymerization in the presence of photoinitiators such as ethylbenzoin. The composition of elastomer could be either a single component elastomer containing an acrylate functional elastomer, or dual component mixture containing an acrylate functional elastomer and an acrylate terminated elastomer. The second type of the UV cure elastomer is a dual-functional system has a vinyl-terminated polydimethylsiloxane and a mercapto functional siloxane. Upon exposure to UV in the presence of a free-radical photoinitiator, Mercapto polymers add to unsaturated resins such as vinyl containing polymers by a free radical mechanism. The composition of this type of elastomer has two components: vinyl terminated polydimethylsiloxane and mercapto functional polydimethysiloxane.

The modulus of the resulting cured elastomers can be manipulated by varying the concentration of the crosslinker. Lowering the crosslinker concentration will result in softer material; increasing the concentration will result in harder material. The number of acrylate functional groups in a unit volume determines the concentration of the crosslinker in the acrylate system. The volumetric unit concentration of vinyl groups governs the crosslink density in the mercapto-vinyl elastomers.

The presence of oxygen may result in incomplete elastomer film exposure. Because oxygen can be ionized by deep UV light, generating ozone. Ozone acts as a filter to the UV light, blocking penetrating to the elastomer. Thus, a nitrogen purge during elastomer film exposure to UV light is necessary. The nitrogen should form a blanket between the film and the UV sources.

### Substrate Surface Modifications

Reasonably good adhesion between substrates and UV cure elastomers in the present invention was observed. However, during the develop process (using solvent to remove unexposed elastomer), a good solvent such as toluene swells the cured elastomer, resulting elastomer volume expanding. This volume expanding may lead to detachment of an elastomer from a substrate. Therefore, additional surface modification of the substrate to improve the adhesion between the substrate and the elastomer, especially for stiffer elastomer, is necessary.

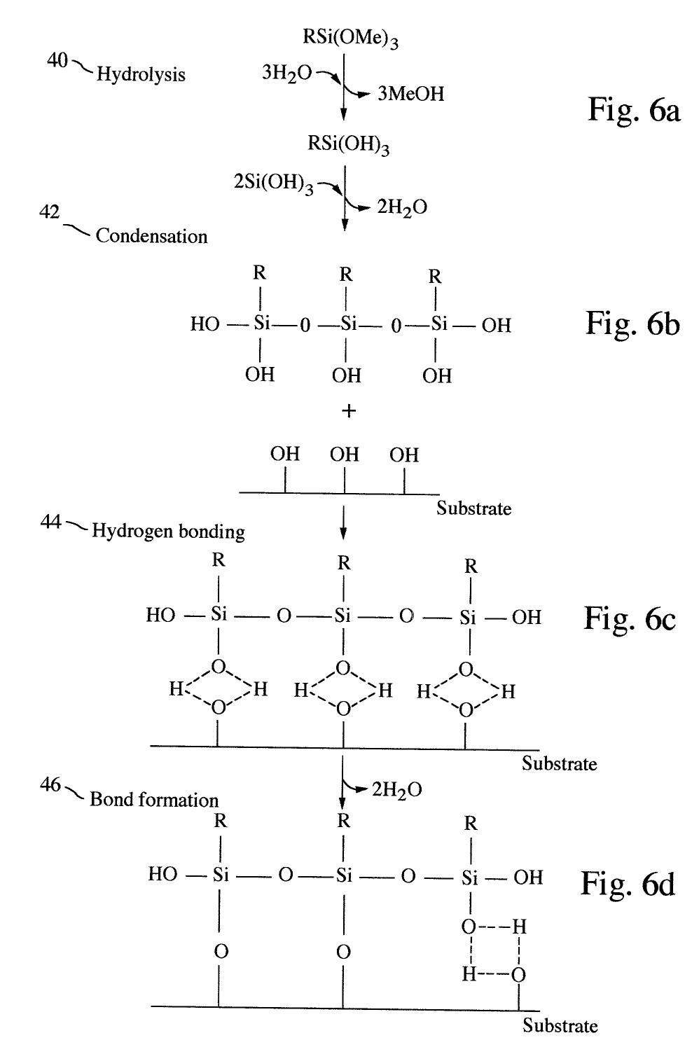

Silanes containing one methacrylate or allyl group and three methoxy groups were used to modify the substrate surfaces in the present invention. Reaction of these silanes involves four steps as shown in FIGS. 6a through 6d. Initially, hydrolysis 40 of the three methoxy groups that are attached to the silicon of the silane occurs. Condensation 42 of two of the three groups to oligomers follows. The oligomers then hydrogen bond 44 with surface OH groups of the substrates (silicon, glass, and metals). Finally, during drying or curing process, a covalent linkage 46 of the one remaining methoxy group is formed with the substrate with concomitant loss of water.

At the interface, there is usually only one bond from each silicon of the silane to the substrate surface. The two remaining silanol groups are present either bonded to other coupling agent silicon atoms or in free form. The methacrylate group on the silanes is selected for acrylate elastomers. Good adhesion between the elastomers and the substrates can be achieved when the acrylate groups in the elastomer bond to the methacrylate groups on the silanes upon irradiation. Allyl functional silanes were chosen for mercapto-vinyl elastomer on the same principal. Covalent bonds were formed between the allyl groups on the surface and the mercapto groups in the elastomers on exposure to UV light.

### Detailed Fabrication Process

The detailed fabrication procedure for lithographically patterning of elastomer thin films depicted in FIGS. 1-4 is described as follows:

(1). Substrate pre-treatment: solvents are used to remove organic contamination on the substrates (silicon, glass, metals and polymers, etc.). It can be achieved by rinsing the substrates with acetone, isopropanol, and water sequentially and then blow-dry the substrates with nitrogen. Oxygen content on the substrate surface can be increased by low dosage plasma treatment such as exposing the substrates with 20 W of oxygen plasma for 30 seconds under high vacuum.

(2). Substrate surface modification: the silanes can be introduced to the substrates by treating the substrates with dilute, weak acidic silane solution such as 2% of silane in ethanol for 5 minutes. The pH of the solution is adjusted to 4.5-5.5 with acetic acid. The treated substrates are rinsed with ethanol and cured at 105OC degree for 5 minutes or room temperature for 24 hours.

(3). Elastomer solution preparation: An elastomer solution is prepared by thoroughly mixing of elastomer(s) with a solvent such as toluene and a minimal amount of photoinitiator such as benzoin ethyl ether. The viscosity of the resulting solution determines the amount of the solvent added. The final concentration of the photoinitiator in the solution is about 0.1-2%. The mixed solution is then degassed under vacuum.

(3). Spin coating: A small amount of elastomer solution (ca. 2-4 ml) is dispensed onto a substrate, which is placed on a programmable spin-coating system. An elastomer thin film is spun by executing a desired spin program. The spin program is determined by the viscosity of the elastomer solution and the desired elastomer film thickness.

(4). Exposure: A mask is aligned above the elastomer film. The gap between the mask and elastomer should be minimal e.g. 30 mm. The elastomer is irradiated by an UV lamp through the mask until the curing is complete. A typical exposure time is about 5-15 seconds using a 100 mW/cm² lamp.

(5). Pattern development: The exposed elastomer film is rinsed with a series of solvents to remove the unexposed elastomer. The types and rinsing sequence of solvents are determined to complete remove the uncured elastomer without leaving any polymer and solvent residuals on the unexposed area. A typical development sequence is to rinse the elastomer films with a mixture of toluene and acetone (20:80) until the unexposed elastomer is completely removed, then rinse the elastomer films sequentially with acetone and water and blow-dry the films with nitrogen.

While several illustrative embodiments of the invention have been shown and described, numerous variations and alternate embodiments will occur to those skilled in the art. Such variations and alternate embodiments are contemplated, and can be made without departing from the spirit and scope of the invention as defined in the appended claims.

I claim:

1. A method, comprising:
Treating the surface of a substrate with an adhesion promoter;
Spinning a UV cure elastomer onto the substrate;
Placing a mask carrying a pattern over the substrate;
Irradiating the surface of the substrate through the mask with UV light; and
Removing the unexposed portions of the elastomer leaving behind patterned elastomer.

2. The method of claim 1, further comprising:
Etching the backside of the substrate to partially release the patterned elastomer.

3. The method of claim 1, wherein the surface is treated with silanes containing one methacrylate or allyl group and three methoxy groups.

4. The method of claim 3, where the surface treatment comprises the following steps:
Hydrolysis of the three methoxy groups that are attached to the silicon of the silane;
Condensation of two of the three methoxy groups to oligomers;
Hydrogen bonding of the oligomers with surface hydroxide (OH) groups on the substrate; and
Covalent linkage of the one remaining methoxy group with the substrate.

5. The method of claim 1, wherein the UV cure elastomer is a mono-functional system that contains acrylate functional groups.

6. The method of claim 5, wherein the UV cure elastomer is a single component elastomer containing an acrylate function elastomer.

7. The method of claim 5, wherein the UV cure elastomer is a dual component mixture containing an acrylate functional elastomer and an acrylate terminated elastomer.

8. The method of claim 1, wherein the UV cure elastomer is a dual-functional system having a vinyl-terminated polydimethylsiloxane and a mercapto functional siloxane.

9. A method, comprising:
Spinning a UV cure elastomer onto a substrate;
Placing a mask carrying a pattern over the substrate;
Irradiating the surface of the substrate through the mask with UV light; and
Removing the unexposed portions of the elastomer leaving behind patterned elastomer.
